(19) United States
(12) Patent Application Publication
(10) Pub. No.: US 2025/0015146 A1
(43) Pub. Date: Jan. 9, 2025

(54) SEMICONDUCTOR DEVICE AND METHOD OF MANUFACTURING THE SAME

(71) Applicant: Renesas Electronics Corporation, Tokyo (JP)

(72) Inventor: Yotaro GOTO, Tokyo (JP)

(21) Appl. No.: 18/763,910

(22) Filed: Jul. 3, 2024

(30) Foreign Application Priority Data
Jul. 7, 2023 (JP) 2023-112391

(51) Int. Cl. H01L 29/40; H01L 29/66; H01L 29/78

(52) U.S. Cl. CPC H01L 29/402; H01L 29/401; H01L 29/66681; H01L 29/7816

(57) ABSTRACT

A dielectric film, which contacts a field plate electrode, is formed between the field plate electrode and a gate electrode, and a recess is formed at an upper surface of the dielectric film and between a drain region and the gate electrode.

### CROSS-REFERENCE TO RELATED APPLICATIONS

The disclosure of Japanese Patent Application No. 2023-112391 filed on Jul. 7, 2023, including the specification, drawings and abstract is incorporated herein by reference in its entirety.

### BACKGROUND

The present invention relates to a semiconductor device and its manufacturing technique, for example, the present invention is applicable to a technique effective for a semiconductor device having a Lateral Diffused Metal Oxide Semiconductor Field Effect Transistor (LDMOSFET) and its manufacturing technique.

There is a disclosed technique listed below.
[Patent Document 1] Japanese Unexamined Patent Application Publication No. 2018-50048
Patent Document 1 discloses a technique to improve the performance of a semiconductor device including an LDMOSFET.

### SUMMARY

For example, LDMOSFET is known as a power device that can be mixed with CMOSFET (Complementary MOSFET). Power devices require improvements in breakdown voltage and reduction in on-resistance, which are in a trade-off relationship. From this, LDMOSFET, which is one of the power devices, also needs to improve both the improvement in breakdown voltage and the reduction in on-resistance.

In one embodiment, a semiconductor device has a dielectric film contacting a field plate electrode between the field plate electrode and a gate electrode, and the dielectric film has a recess at an upper surface of the dielectric film between the drain region and the gate electrode to reduce a distance between the field plate electrode and a lower end of the gate electrode. And, a part of the field plate electrode is buried in the recess.

In one embodiment, a method of manufacturing a semiconductor device includes a step of forming a dielectric film so as to contact a part of an upper surface of a gate electrode, a sidewall spacer, and a semiconductor substrate, and in this step, the dielectric film is formed by using a normal pressure CVD method or a plasma CVD method.

According to one embodiment, the performance of the semiconductor device including LDMOSFET can be improved.

### BRIEF DESCRIPTION OF THE DRAWINGS

FIG. 1 is a cross-sectional view showing a structure of a semiconductor device including an LDMOSFET.

FIG. 2 is an enlarged view showing the configuration between the lower end of the field plate electrode and the gate electrode.

FIG. 3 is a diagram schematically explaining the difference between the recess and the surface roughness of the dielectric film.

FIG. 4 is a diagram showing a manufacturing step of the semiconductor device in an embodiment.

FIG. 5 is a diagram showing a manufacturing step of the semiconductor device following FIG. 4.

FIG. 6 is a diagram showing a manufacturing step of the semiconductor device following FIG. 5.

FIG. 7 is a diagram showing a manufacturing step of the semiconductor device following FIG. 6.

FIG. 8 is a diagram showing a manufacturing step of the semiconductor device following FIG. 7.

FIG. 9 is a diagram showing a manufacturing step of the semiconductor device following FIG. 8.

FIG. 10 is a diagram showing a manufacturing step of the semiconductor device following FIG. 9.

FIG. 11A is a diagram showing the “slope region” existing in the recess and the “recess amount” of the recess.

FIG. 11B is a graph showing the relationship between the recess amount and the breakdown voltage.

FIG. 12 is a plan view showing a schematic configuration of a semiconductor device in a first modified example.

FIG. 13 is a cross-sectional view of the semiconductor device along line A-A of FIG. 12.

FIG. 14 is a cross-sectional view of the semiconductor device along line B-B of FIG. 12.

FIG. 15 is an enlarged view showing a part of FIG. 14.

FIG. 16 is an enlarged view showing a configuration between the field plate electrode and the lower end of the gate electrode in a second modified example.

FIG. 17 is an enlarged view showing a configuration between the field plate electrode and the lower end of the gate electrode in a third modified example.

FIG. 18 is an enlarged view showing a configuration between the field plate electrode and the lower end of the gate electrode in a fourth modified example.

FIG. 19 is a plan view showing a schematic configuration of the semiconductor device in a fifth modified example.

FIGS. 20A and 20B are enlarged views showing the configuration between the field plate electrode and the sidewall spacer.

### DETAILED DESCRIPTION

In all the drawings for explaining the embodiments, the same members are denoted by the same reference numerals in principle, and repetitive descriptions thereof are omitted. Note that even plan view may be hatched for the sake of clarity.

### Usefulness of Field Plate Electrode

For example, an LDMOSFET has a source region and a drain region formed in a semiconductor substrate, and a gate electrode disposed on the semiconductor substrate via a gate dielectric film. The characteristic of the LDMOSFET is that a distance between the gate electrode and the drain region is greater than a distance between the gate electrode and the source region.

This allows a width of the depletion layer extending from the drain region to be increased when the LDMOSFET is turned off. This can relax the electric field in the depletion layer. Therefore, the breakdown voltage of the LDMOSFET can be improved.

On the other hand, the LDMOSFET also requires to reduce the on-resistance of the LDMOSFET. For example, to reduce the on-resistance, increasing the impurity concentration of the drift region is considered. However, if the impurity concentration in the drift region increases, the depletion layer is less likely to extend from the drain region. And the interval between the equipotential lines in the depletion layer decreases and the electric field increases. Therefore, if the impurity concentration of the drift region increases to reduce the on-resistance, it leads to a decrease in breakdown voltage.

Therefore, forming a field plate electrode on the LDMOSFET in order to improve the breakdown voltage while reducing the on-resistance. Specifically, the field plate electrode is formed on the upper surface of the semiconductor substrate to cover a part of the gate electrode, and a reference potential (0 V) is supplied to the field plate electrode. This field plate electrode can widen the interval between the equipotential lines in the drift region caused by the potential difference between the source region and the drain region, and the electric field in the drift region is relaxed. From this, the breakdown voltage can be improved by forming a field plate electrode on the LDMOSFET. Thus, the LDMOSFET with the field plate electrode can secure a breakdown voltage while reducing the on-resistance.

### Novel Findings by Inventor

When increasing the impurity concentration of the drift region to reduce the on-resistance, simply forming the field plate electrode may not be sufficient from the viewpoint of improving the breakdown voltage. The inventor has newly found that it is necessary to devise a way to improve the breakdown voltage.

Specifically, even if the field plate electrode is formed on the LDMOSFET, depending on the distance between the field plate electrode and the lower end of the gate electrode, there is a risk that the breakdown voltage cannot be secured. This is because when the impurity concentration increases, the interval between the equipotential lines decreases, and the equipotential lines are likely to enter between the field plate electrode and the lower end of the gate electrode. And the entry of the equipotential lines between the field plate electrode and the lower end of the gate electrode means that the interval between the equipotential lines decreases and the electric field strength increases. As a result, for example, the electric field concentration occurring at the lower end of the gate electrode leads to a decrease in breakdown voltage at this lower end of the gate electrode. Thus, the inventor has found that when the impurity concentration of the drift region increases, there is a risk that the effect of improving the breakdown voltage (electric field relaxation effect) by the field plate electrode cannot be sufficiently obtained.

Therefore, in the present embodiment, in the LDMOSFET having the field plate electrode, attention is paid to the distance between the field plate electrode and the lower end of the gate electrode, and the breakdown voltage of the LDMOSFET having the field plate electrode is improved. The technical idea in the present embodiment will be described below.

### Basic Concept in Embodiment

The basic concept in the present embodiment is to reduce the distance between the field plate electrode and the lower end of the gate electrode. Even if the interval between equipotential lines in the drift region is reduced by increasing the impurity concentration of the drift region, it becomes difficult for equipotential lines to enter between the field plate electrode and the lower end of the gate electrode. The difficulty of equipotential lines entering means that the interval between equipotential lines can be suppressed in the interval between the field plate electrode and the lower end of the gate electrode. As a result, the basic concept can suppress an increase in the electric field strength between the field plate electrode and the lower end of the gate electrode. From this, the basic concept can suppress the electric field concentration at the lower end of the gate electrode from causing a decrease in breakdown voltage. Therefore, the basic concept can improve the performance of a semiconductor device including an LDMOSFET.

When embodying the basic concept described above, the impact on the characteristics of devices such as CMOSFETs that are mixed with the LDMOSFET needs to be considered. That is, the LDMOSFET has a structure suitable for the CMOSFET mixed with the LDMOSFET. And, the basic concept can be embodied in a semiconductor device where the LDMOSFET and the CMOSFET are mixed, while minimizing the impact on the characteristics of the CMOSFET.

For example, reducing the width of the sidewall spacer formed on the side surface of the gate electrode is considered by adding a manufacturing step. According to this, the distance between the field plate electrode and the lower end of the gate electrode can be reduced. However, the CMOSFET also has a sidewall spacer, and the width of the sidewall spacer of the CMOSFET is also reduced. The reduction in the width of the sidewall spacer of the CMOSFET may cause a change in the characteristics of the CMOSFET.

Therefore, in the present embodiment, the impact on the characteristics of the CMOSFET mixed with the LDMOSFET is minimized when embodying the basic concept. Below, an embodiment mode embodying the basic concept described above, considering minimizing the impact on the characteristics of the CMOSFET, will be described.

### Embodiment Mode

First, the concept of the embodiment mode will be explained.

For example, the concept of the embodiment mode is that when a dielectric film contacting the field plate electrode exists between the field plate electrode and the gate electrode, a recess is formed at the upper surface of the dielectric film and between the drain region and the gate electrode (between the field plate electrode and the gate electrode). In addition, a part of the field plate electrode is buried in the recess. This allows the distance between the field plate electrode and the lower end of the gate electrode to be reduced.

Below, the details of the embodiment mode based on the concept described above will be explained.

### Structure of Semiconductor Device

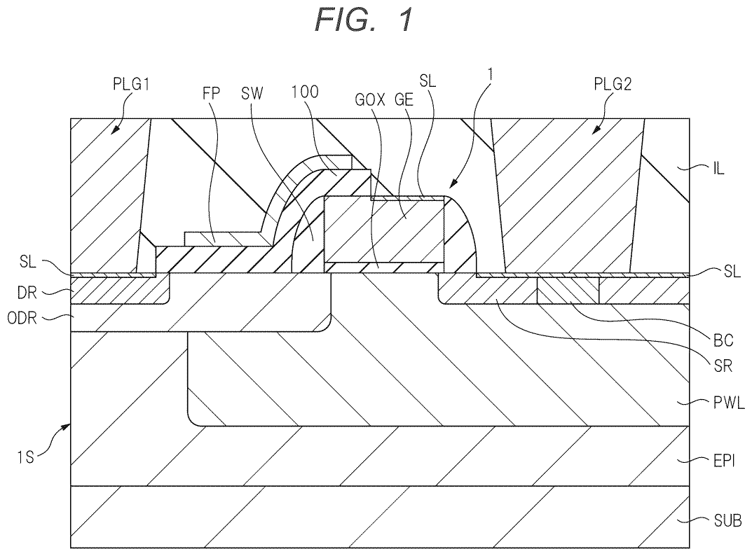

FIG. 1 is a cross-sectional view showing a structure of a semiconductor device including an LDMOSFET 1.

The LDMOSFET 1 includes a semiconductor substrate SUB, an epitaxial layer EPI, a p-type well PWL, a gate dielectric film GOX, a gate electrode GE, a sidewall spacer SW, a source region SR, a drain region DR, an offset drain region ODR, a dielectric film 100, a field plate electrode FP, and a body contact region BC.

As shown in FIG. 1, the epitaxial layer EPI is formed on the semiconductor substrate SUB. The semiconductor substrate SUB is formed of, for example, monocrystalline silicon into which an n-type impurity (donor) such as arsenic (As) is introduced. The epitaxial layer EPI is also formed of monocrystalline silicon into which an n-type impurity is introduced. The laminated body formed of the semiconductor substrate SUB and the epitaxial layer EPI may be referred to as a substrate 1S.

This epitaxial layer EPI functions as a drift region. An impurity concentration of the epitaxial layer EPI is lower than an impurity concentration of the semiconductor substrate SUB.

Next, the p-type well PWL, which is a p-type semiconductor region, is formed in an upper part of the epitaxial layer EPI. This p-type well PWL is also referred to as a p-type body region. The p-type well PWL functions as a punch-through stopper that suppresses “punch-through” when the LDMOSFET 1 is turned off. “Punch-through” occurs when the depletion layer reaches from the drain region DR to the source region SR.

Subsequently, the gate electrode GE is formed on the substrate 1S via the gate dielectric film GOX. The gate dielectric film GOX is, for example, formed of a silicon oxide film. The gate electrode GE is formed, for example, from a polysilicon film and a metal silicide SL formed on an upper surface of the polysilicon film. The sidewall spacer SW, which is, for example, formed of a silicon oxide film, is formed on a side surface of the gate electrode GE.

The source region SR and the offset drain region ODR are formed in the epitaxial layer EPI. The source region SR and the offset drain region ODR are separated from each other and sandwich a channel formation region formed at the upper surface of the p-type well PWL.

The channel formation region corresponds to the region directly below the gate electrode GE. In this channel formation region, a channel formed of an inversion layer is formed when a gate voltage equal to or higher than the threshold voltage is applied to the gate electrode GE.

The metal silicide SL is formed on the upper surface of the source region SR. In this specification, this metal silicide SL is also included in the source region SR. The drain region DR is formed in the epitaxial layer EPI so as to contact the offset drain region ODR. The metal silicide SL is formed on the upper surface of the drain region DR. In this specification, this metal silicide SL is also included in the drain region DR. The depth of the drain region DR is shallower than the depth of the offset drain region ODR. Also, the impurity concentration of the drain region DR is higher than the impurity concentration of the offset drain region ODR.

In the LDMOSFET 1, the offset drain region ODR is formed between the drain region DR and the gate electrode GE. From this, in the LDMOSFET 1, the distance between the gate electrode GE and the drain region DR is greater than the distance between the gate electrode GE and the source region SR. That is, in the LDMOSFET 1, the source region SR and the drain region DR are formed asymmetrically with respect to the gate electrode GE.

This allows the depletion layer to be sufficiently extended from the drain region DR to the offset drain region ODR when the LDMOSFET 1 is turned off, thereby improving the breakdown voltage between the source region SR and the drain region DR. That is, the offset drain region ODR is formed to secure sufficient breakdown voltage.

Next, as shown in FIG. 1, the dielectric film 100 is formed so as to contact the substrate 1S, the sidewall spacer SW, and a part of the upper surface of the gate electrode GE. The dielectric film 100 is, for example, formed of a silicon oxide film. Then, the field plate electrode FP is formed on the dielectric film 100 so as to contact the dielectric film 100. That is, the field plate electrode FP is continuously formed on the part of the gate electrode GE, on the sidewall spacer SW formed on the side surface of the gate electrode GE facing the drain region DR, and on the offset drain region ODR. The field plate electrode FP is, for example, formed from a metal silicide film.

An interlayer dielectric film IL is formed so as to cover the LDMOSFET 1. The interlayer dielectric film IL is, for example, formed of a silicon oxide film. Then, as shown in FIG. 1, a plug PLG1 reaching the drain region DR and a plug PLG2 reaching the source region SR are formed in the interlayer dielectric film IL.

Here, the body contact region BC, which is formed of a p-type semiconductor region, is formed in the substrate 1S so as to contact the source region SR. The plug PLG2 is electrically connected not only to the source region SR but also to the body contact region BC. Therefore, in the LDMOSFET 1, the source region SR and the body contact region BC have the same potential. Since the body contact region BC is connected to the p-type well PWL, the p-type well PWL and the source region SR are connected at the same potential. As a result, according to the LDMOSFET 1, a potential difference is less likely to occur between the p-type well PWL and the source region SR. This can suppress the parasitic npn bipolar transistor, which is formed of the source region SR, the p-type well region PWL, and the semiconductor substrate SUB (epitaxial layer EPI), from turning on. That is, the LDMOSFET 1 can suppress “latch-up” caused by the parasitic bipolar transistor.

The LDMOSFET 1 is configured as described above.

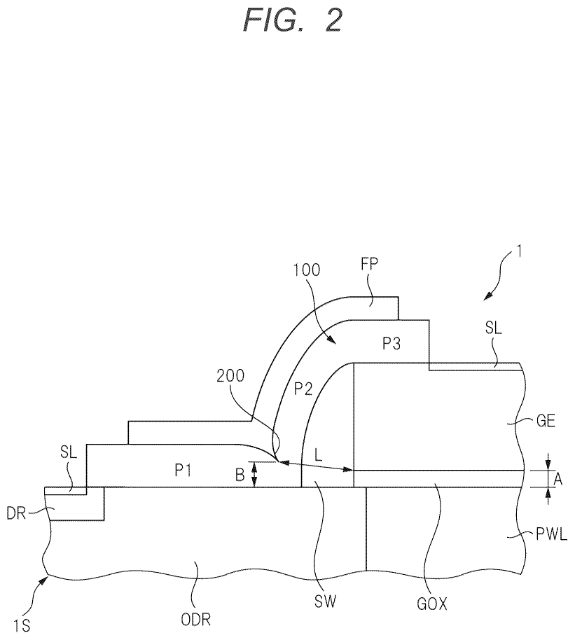

Next, a detailed configuration between the field plate electrode FP and the lower end of the gate electrode GE will be described. FIG. 2 is an enlarged view showing the configuration between the field plate electrode FP and the lower end of the gate electrode GE. In the following, the dielectric film 100 located under the field plate electrode FP will be particularly described.

In FIG. 2, the dielectric film 100 has a first part P1 contacting the substrate 1S, a second part P2 contacting the sidewall spacer SW, and a third part P3 contacting a part of the upper surface of the gate electrode GE. Also, a recess 200 is formed at the connection point between the upper surface of the first part P1 and the upper surface of the second part P2. A part of the field plate electrode FP is buried in the recess 200. In the LDMOSFET 1 configured as described above, as shown in FIG. 2, the “distance B” (first distance) between the upper surface of the substrate 1S and the recess 200 is greater than the “thickness A” of the gate dielectric film GOX. In this case, the “distance B” is the shortest distance between the upper surface of the substrate 1S and the lower end of the recess 200 in a direction perpendicular to the upper surface of the substrate 1s.

Here, the upper surface of the dielectric film 100 has an unevenness corresponding to the surface roughness. In this regard, the recess 200 formed at the connection point between the upper surface of the first part P1 and the upper surface of the second part P2 of the dielectric film 100 is greater than the above-mentioned an unevenness, and the recess 200 is distinguished from the above-mentioned an unevenness.

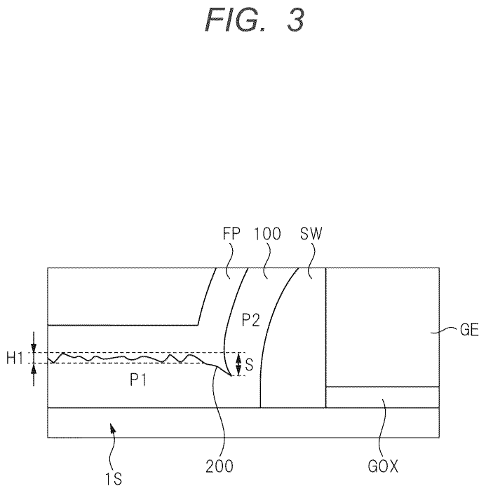

In the following, the difference between the recess 200 and the unevenness corresponding to the surface roughness will be described with reference to FIG. 3.

FIG. 3 is a diagram showing the difference between the recess 200 and the surface roughness of the dielectric film 100. In FIG. 3, the recess 200 is formed at the connection point between the first part P1 and the second part P2 of the dielectric film 100. As shown in FIG. 3, the unevenness corresponding to the surface roughness is formed on the upper surface of the first part P1 of the dielectric film 100. The distance “S” (first difference) between the highest position of the unevenness and the lowest position of the recess 200 is greater than the difference “Hi” (second difference) between the highest position and the lowest position of the unevenness. Specifically, the distance “S” is greater than 2 nm. In this way, in the embodiment mode, the recess 200 is clearly distinguished from the unevenness corresponding to the surface roughness.

### Manufacturing Method of Semiconductor Device

Next, the manufacturing method of the semiconductor device will be described with reference to the drawings.

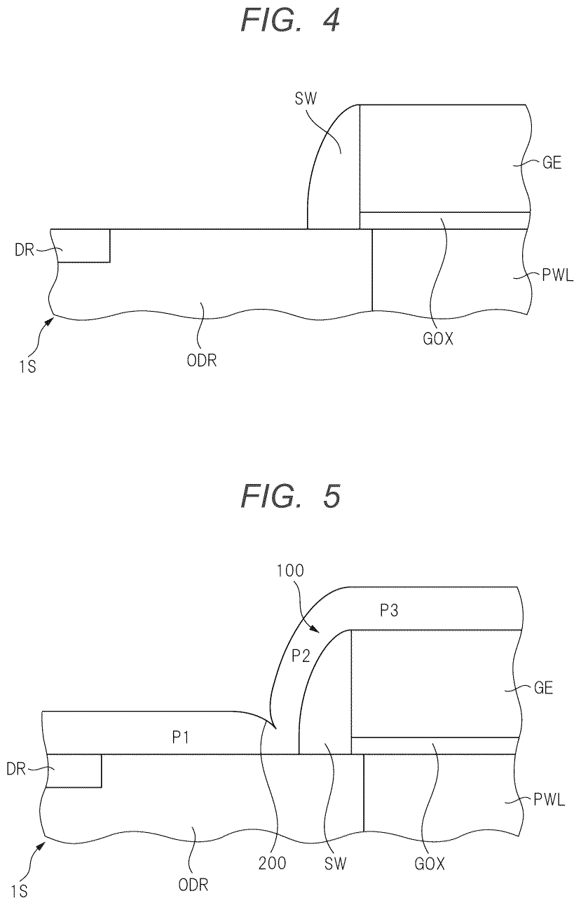

First, as shown in FIG. 4, the p-type well PWL, the offset drain region ODR, and the drain region DR are formed in the substrate 1S, and the gate electrode GE is formed on the upper surface of the substrate 1S via the gate dielectric film GOX. Then, the sidewall spacer SW is formed on the side surface of the gate electrode GE. Next, as shown in FIG. 5, the dielectric film 100 is formed so as to cover the upper surface of the substrate 1S (offset drain region ODR and drain region DR), the sidewall spacer SW, and the gate electrode GE.

The dielectric film 100 is formed, for example, by using a normal pressure CVD (Chemical Vapor Deposition) method or a plasma CVD method. The film formation conditions when forming the dielectric film 100 using the normal pressure CVD method are as follows. For example, the film formation temperature is 380 degrees Celsius. The source gas is silane gas (SiH4) and oxygen gas (O₂). Furthermore, the film formation pressure is 760 Torr (1 Torr=133.32 Pa).

On the other hand, the film formation conditions when forming the dielectric film 100 using the plasma CVD method are as follows. For example, the film formation temperature is 400 degrees Celsius. The source gas is TEOS and oxygen gas. Furthermore, the film formation pressure is 3 Pa.

As shown in FIG. 5, the dielectric film 100 in the embodiment mode includes the first part P1 contacting the substrate 1S, the second part P2 contacting the sidewall spacer SW, and the third part P3 contacting the upper surface of the gate electrode GE. By using the normal pressure CVD method or the plasma CVD method, the thickness uniformity of the dielectric film 100 decreases, and the recess 200 is formed at the connection point between the upper surface of the first part P1 and the upper surface of the second part P2. That is, in the embodiment mode, the recess 200 is intentionally formed.

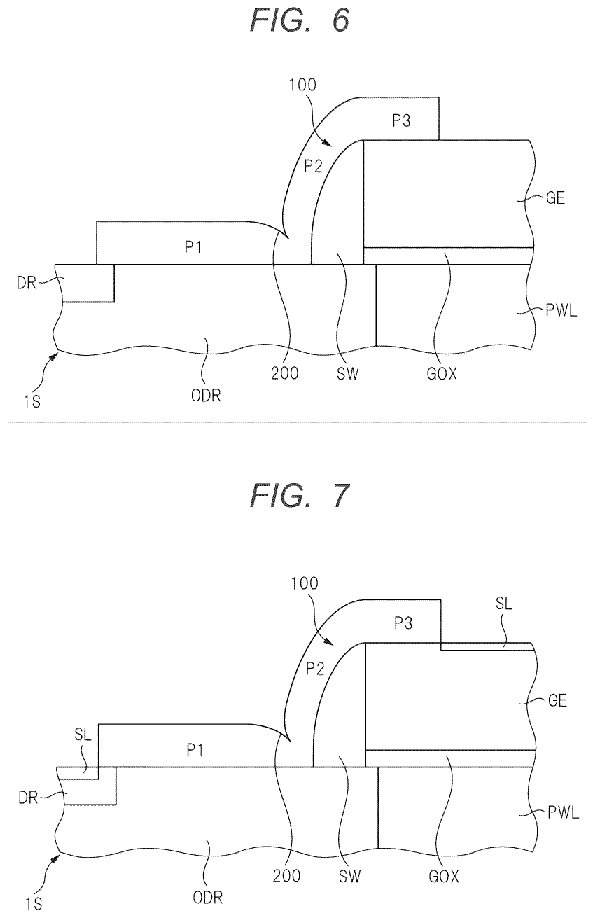

Next, as shown in FIG. 6, the dielectric film 100 is patterned using a photolithography technique and an etching technique. As a result, the dielectric film 100 covers a part of the upper surface of the gate electrode GE and exposes the other part of the upper surface of the gate electrode GE. By patterning the dielectric film 100, the dielectric film 100 is formed of the first part P1, the second part P2, and the third part P3 contacting a part of the upper surface of the gate electrode GE. Then, as shown in FIG. 7, the metal silicide SL is formed on the upper surface of the substrate 1S and the other part of the upper surface of the gate electrode GE exposed from the dielectric film 100 by using a silicide technique.

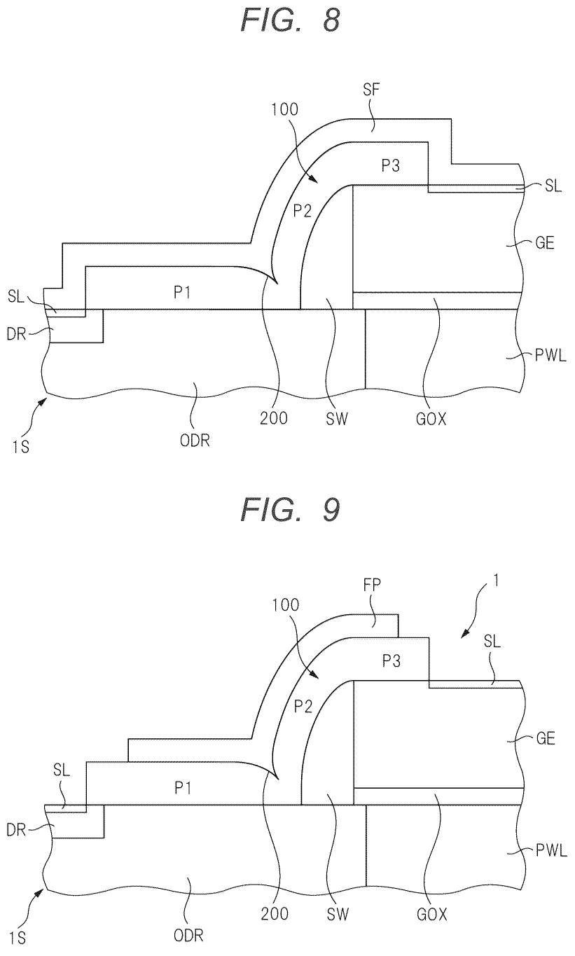

Next, as shown in FIG. 8, for example, a tungsten silicide film SF is formed to cover the dielectric film 100 and the gate electrode GE by using a sputtering method. Then, as shown in FIG. 9, the tungsten silicide film SF is patterned using a photolithography technique and an etching technique to form the field plate electrode FP. At this time, a part of the field plate electrode FP is buried in the recess 200. In this way, the LDMOSFET 1 can be formed.

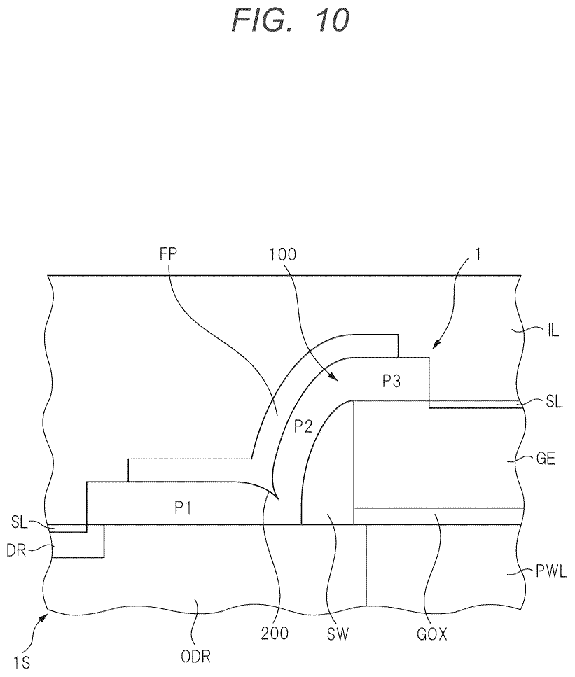

Afterwards, as shown in FIG. 10, for example, the interlayer dielectric film IL is formed to cover the LDMOSFET 1 formed on the substrate 1S. The interlayer dielectric film IL is formed of, for example, a silicon oxide film. Then, although not shown, a plug penetrating through the interlayer dielectric film IL and a wiring connected to the plug are formed. As a result, a semiconductor device including the LDMOSFET 1 in the embodiment mode can be manufactured.

### Features in Embodiment Mode

Next, the features in the embodiment mode will be described.

The first feature in the embodiment mode is that, as shown in FIG. 2, for example, the recess 200 is formed at the connection point between the upper surface of the first part P1 and the upper surface of the second part P2 of the dielectric film 100 located under the field plate electrode FP. As a result, a part of the field plate electrode FP is buried in the recess 200, so the distance “L” between the lower end of the field plate electrode FP and the gate electrode GE can be made smaller than the configuration without the recess 200.

According to such a first feature, even if the distance between the equipotential lines in the drift region decreases by increasing the impurity concentration of the drift region (inside the substrate 1S), the distance “L” shown in FIG. 2 decreases due to the presence of the recess 200. Therefore, the equipotential lines are less likely to enter between the field plate electrode FP and the lower end of the gate electrode GE. Therefore, the distance between the equipotential lines can be suppressed from decreasing between the field plate electrode FP and the lower end of the gate electrode GE. As a result, according to the first feature, even if the impurity concentration of the drift region of the LDMOSFET 1 increases to reduce the on-resistance of the LDMOSFET 1, an increase in the electric field strength between the field plate electrode FP and the lower end of the gate electrode GE can be suppressed. From this, the first feature can suppress the decrease in breakdown voltage caused by the electric field concentration at the lower end of the gate electrode GE while reducing the on-resistance of the LDMOSFET 1. In other words, the first feature can improve both the reduction of on-resistance and the improvement of breakdown voltage, which are in a trade-off relationship with each other. Therefore, the first feature can improve the performance of the semiconductor device including the LDMOSFET 1.

As described above, forming the recess 200 in the dielectric film 100 can improve the breakdown voltage of the LDMOSFET 1. In this regard, if the recess 200 is formed, the breakdown voltage can be improved, so the shape of the recess 200 is not limited to the shape shown in FIG. 2. This is because the technical significance of forming the recess 200 is to reduce the distance “L” between the field plate electrode FP and the lower end of the gate electrode GE. In other words, by the presence of the recess 200, if the distance “L” is reduced, equipotential lines are less likely to enter between the field plate electrode FP and the lower end of the gate electrode GE.

On the other hand, the present inventor have clarified that when the size of the recess 200 changes, a certain difference occurs in the effect of improving the breakdown voltage, so the following will explain this point.

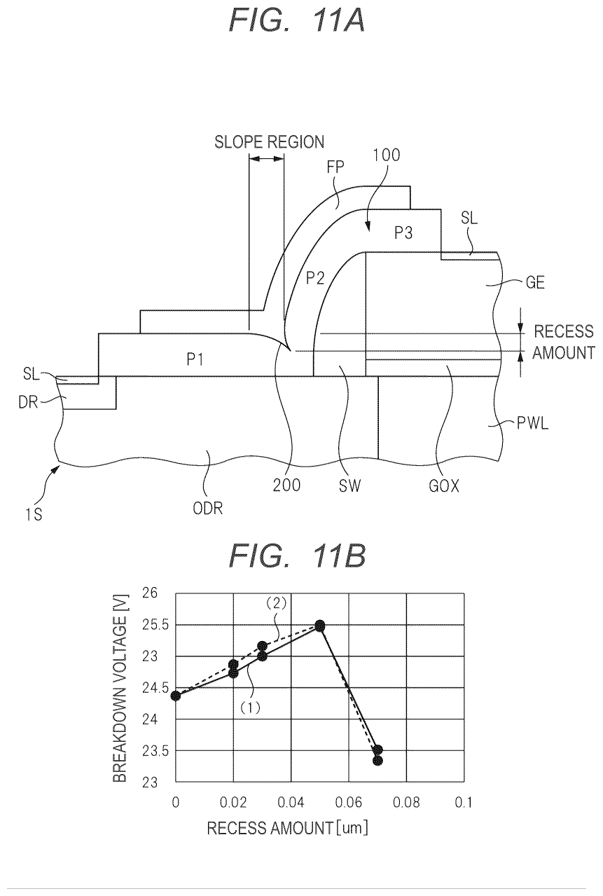

FIGS. 11A and 11B are diagrams explaining the size dependence of the recess on the breakdown voltage. FIG. 11A is a diagram showing the “slope region” existing in the recess 200 and the “recess amount” of the recess, and FIG. 11B is a graph showing the relationship between the recess amount and the breakdown voltage.

The “slope region” and “recess amount” of the recess 200 are defined as shown in FIG. 11A. The “slope region” corresponds to the horizontal length of the upper surface of the first part P1, which is inclined with respect to the upper surface of the substrate 1S. The “recess amount” corresponds to the distance between the highest position of the upper surface of the first part P1 and the lower end of the recess in the direction perpendicular to the upper surface of the substrate 1S.

In FIG. 11B, graph (1) shows the relationship between the recess amount corresponding to the recess 200 and the breakdown voltage where the “slope region=0.03 μm”. On the other hand, graph (2) shows the relationship between the recess amount corresponding to the recess 200 and the breakdown voltage where the “slope region=0.09 μm”.

As shown in FIG. 11B, the same trend obtained in both graph (1) and graph (2) will be explained. That is, as the “recess amount” increases, the breakdown voltage improves (first trend), but when the “recess amount” exceeds “0.05 μm”, the breakdown voltage decreases (second trend). Here, the increase in the “recess amount” means that the size of the recess 200 increases. From this, the first trend indicates that as the size of the recess 200 increases, the distance “L” decreases, and the entry of equipotential lines is sufficiently suppressed.

The increase in the “recess amount” means that the distance between the recess 200 and the upper surface of the substrate 1S, or in other words, the thickness of the dielectric film 100 directly below the recess 200 decreases. And as the “recess amount” increases, the thickness of the dielectric film 100 directly below the recess 200 decreases than the thickness of the gate dielectric film GOX. In this case, it is considered that the portion with a small thickness of the dielectric film 100 directly below the recess 200 behaves as a hotspot for breakdown voltage reduction. In other words, the second trend indicates that as the size of the recess 200 increases and the thickness of the dielectric film 100 directly below the recess 200 decreases than the thickness of the gate dielectric film GOX, the region directly below the recess 200 behaves as a hotspot for breakdown voltage reduction.

From the above, in order to improve the breakdown voltage by forming the recess 200, it is desirable to increase the size (“recess amount”) of the recess 200 so that the thickness of the dielectric film 100 directly below the recess 200 does not decrease than the thickness of the gate dielectric film GOX.

Subsequently, the second feature in the embodiment mode is, for example, as shown in FIG. 5, to form the dielectric film 100 by using a normal pressure CVD method or a plasma CVD method. By changing the method of forming the dielectric film 100 from a low-pressure CVD method to a normal pressure CVD method or a plasma CVD method, as shown in FIG. 5, the recess 200 can be formed at the connection point between the upper surface of the first part P1 and the upper surface of the second part P2 of the dielectric film 100.

A film with lower thickness uniformity than the film formed by the low-pressure CVD method is formed by the normal pressure CVD method or the plasma CVD method. As a result, the recess 200 as shown in FIG. 5 can be formed at the connection point between the upper surface of the first part P1 and the upper surface of the second part P2 of the dielectric film 100.

For example, generally, it is desirable that the dielectric film 100 is a conformal film with high thickness uniformity. For this reason, a low-pressure CVD method is used as the method of forming the dielectric film 100.

In this regard, the present inventor has focused on the point that if the dielectric film 100 with low thickness uniformity is formed instead of daringly forming a conformal dielectric film 100 with high thickness uniformity, the recess 200 is inevitably formed. In particular, the inventor has noted that films formed by normal pressure CVD method or plasma CVD method have lower thickness uniformity than films formed by low pressure CVD method, and is actively using normal pressure CVD method or plasma CVD method, which are not usually used as a method for forming the dielectric film 100.

For example, when using the normal pressure CVD method, in order to easily form the recess 200 in the dielectric film 100, it is desirable to lower the film formation temperature (about 380 degrees Celsius or more and 420 degrees Celsius or less). On the other hand, when using the plasma CVD method, in order to easily form the recess 200 in the dielectric film 100, it is desirable to (1) lower the film formation temperature (about 380 degrees Celsius or more and 420 degrees Celsius or less), (2) increase the pressure (about 3 Pa or more and 4 Pa or less), or (3) change the balance between high frequency and low frequency (high frequency: about 13 MHz or more and 14 MHz or less, low frequency: about 250 kHz or more and 400 kHz or less).

According to the second feature in the embodiment as described above, the recess 200 can be formed in the dielectric film 100 while reducing the impact on the characteristics of devices such as CMOSFETs that are mixed with the LDMOSFET 1. This is because the field plate electrode FP and the underlying film, which is the dielectric film 100, are inherent components of the LDMOSFET 1. That is, the dielectric film 100 is not left in the CMOSFET, so changing the method of forming the dielectric film 100 does not affect the structure of the CMOSFET. Therefore, the second feature in the embodiment can improve the breakdown voltage of the LDMOSFET 1 without affecting the characteristics of the CMOSFET.

Furthermore, in the embodiment mode, the material of the field plate electrode FP is selected so as not to affect the characteristics of the CMOSFET. For example, titanium nitride (TiN) may be adopted as the material of the field plate electrode FP. This titanium nitride melts in the cleaning process called “APM process/SPM process”, so there may be cases where defects occur in the formation of the field plate electrode FP. Therefore, when the field plate electrode FP is formed of titanium nitride, the cleaning conditions of the cleaning process used in the step of forming the contact hole reaching the field plate electrode FP need to change. In this regard, not only the contact hole reaching the field plate electrode FP, but also the contact hole reaching the CMOSFET (source region, drain region, and gate electrode) is formed. Therefore, changing the cleaning conditions means that the cleaning conditions of the cleaning process for the contact hole reaching the CMOSFET are also changed. Therefore, changing the cleaning conditions of the cleaning process for the contact hole may affect the characteristics of the CMOSFET. That is, when the field plate electrode FP is formed of titanium nitride, changing the cleaning conditions of the cleaning process for the contact hole may affect the characteristics of the CMOSFET.

Therefore, in the embodiment mode, the field plate electrode FP is formed of a metal silicide (for example, tungsten silicide). This is because metal silicide does not melt in the “APM process/SPM process”, so the cleaning conditions do not need to change.

In addition, from the viewpoint of suppressing the impact on the characteristics of the CMOSFET, the field plate electrode FP does not need to be formed from a polysilicon film. This is because the film formation temperature of the polysilicon film is higher than the formation temperature of the metal silicide, and there is a concern that the characteristics of the CMOSFET may change due to heat.

From the above, in the embodiment mode, by forming the field plate electrode FP from a metal silicide film, not a titanium nitride film or a polysilicon film, the field plate electrode FP can be realized without adversely affecting the characteristics of the CMOSFET mixed with the LDMOSFET 1.

### First Modified Example

Next, a semiconductor device in the first modified example will be described.

### Structure of Semiconductor Device

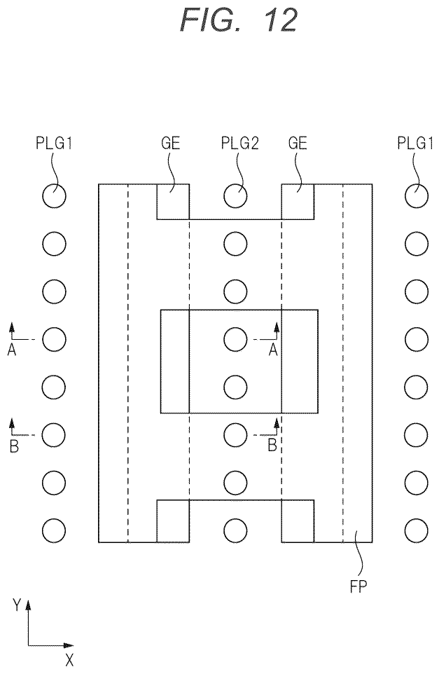

FIG. 12 is a plan view showing a schematic configuration of the semiconductor device in the first modified example.

In FIG. 12, the plurality of plugs PLG1 (in FIG. 12, eight plugs PLG1) are disposed to be separated in the Y direction. Also, the plurality of plugs PLG1 (in FIG. 12, two plugs PLG1) are disposed to be separated in the X direction. That is, in FIG. 12, a “plug row” formed of eight plugs PLG1 disposed in the Y direction is disposed in two rows in the X direction. Between the two rows of “plug rows” disposed in this way, a “plug row” formed of eight plugs PLG2 disposed in the Y direction is disposed. Here, the plug PLG1 is electrically connected to the drain region. On the other hand, the plug PLG2 is electrically connected to the source region.

Next, as shown in FIG. 12, between the “plug row” on the left side and the “plug row” in the center, and between the “plug row” in the center and the “plug row” on the right side, the gate electrode GE extends in the Y direction. The width of the gate electrode GE in the Y direction is the gate width. On the other hand, the width of the gate electrode GE in the X direction is the gate length. And, the field plate electrode FP, which partially overlaps the gate electrode GE in plan view, extends in the Y direction. That is, as shown in FIG. 12, the field plate electrode FP in the first modified example has a left extension part and a right extension part, the left extension part extends in the Y direction while partially overlapping the left gate electrode GE, and the right extension part extends in the Y direction while partially overlapping the right gate electrode GE. And, the left extension part and the right extension part are connected to each other by a plurality of connection parts extending in the X direction. In this way, the field plate electrode FP in the first modified example is formed of the left extension part, the right extension part, and the plurality of connection parts. In FIG. 12, the part where the gate electrode GE overlaps the field plate electrode FP is shown by a dotted line.

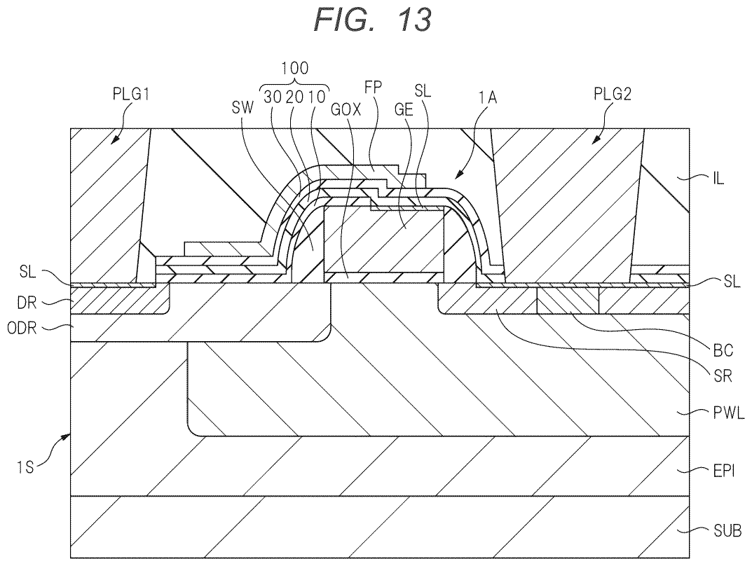

Next, FIG. 13 is a cross-sectional view of the semiconductor device along line A-A in FIG. 12.

In FIG. 13, an LDMOSFET 1A has the dielectric film 100 formed to contact a part of the upper surface of the gate electrode GE, the sidewall spacer SW, and the substrate 1S.

As shown in FIG. 13, the dielectric film 100 is formed of a dielectric film 10, a dielectric film 20, and a dielectric film 30. The dielectric film 10 is formed to contact a part of the upper surface of the gate electrode GE, the sidewall spacer SW, and the substrate 1S. The dielectric film 20 is formed to contact the other part (remaining part) of the upper surface of the gate electrode GE and the dielectric film 10, and to cover the gate electrode GE. The dielectric film 30 is formed to contact the dielectric film 20 and to cover the gate electrode GE. And, the field plate electrode FP in the first modified example is formed to contact the dielectric film 30.

The dielectric film 10 is formed, for example, from a silicon oxide film. The dielectric film 20 is formed, for example, from a silicon nitride film. Also, the dielectric film 30 is formed, for example, from a silicon oxide film. The thickness uniformity of the dielectric film 20 is higher than the thickness uniformity of each of the dielectric film 10 and the dielectric film 30.

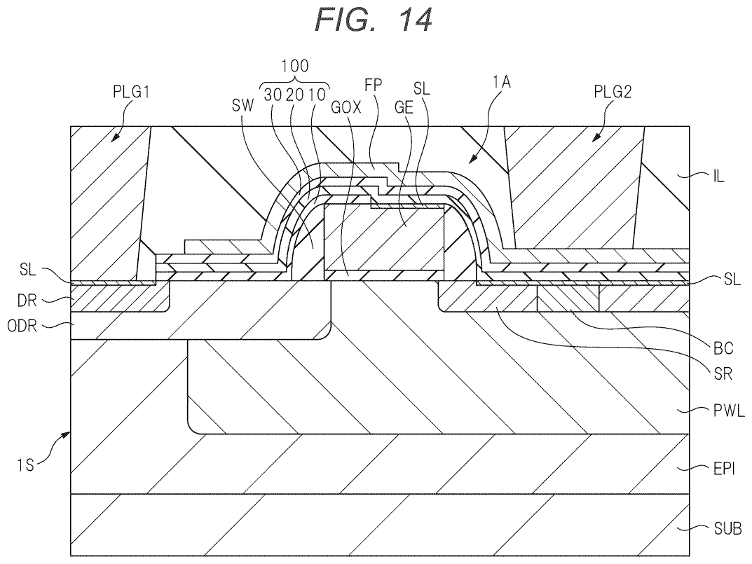

Next, FIG. 14 is a cross-sectional view of the semiconductor device along line B-B in FIG. 12.

In FIG. 14, the field plate electrode FP contacts the dielectric film 30. Furthermore, the field plate electrode FP extends to cover the gate electrode GE and to be electrically connected to the plug PLG2. Here, the plug PLG2 shown in FIG. 13 is electrically connected to the source region SR. Also, the plug PLG2 shown in FIG. 14 is electrically connected to the field plate electrode FP. And, although not shown, the plug PLG2 shown in FIG. 13 and the plug PLG2 shown in FIG. 14 are electrically connected by a wiring formed on the interlayer dielectric film IL, for example. That is, the same potential is applied to the field plate electrode FP and the source region SR.

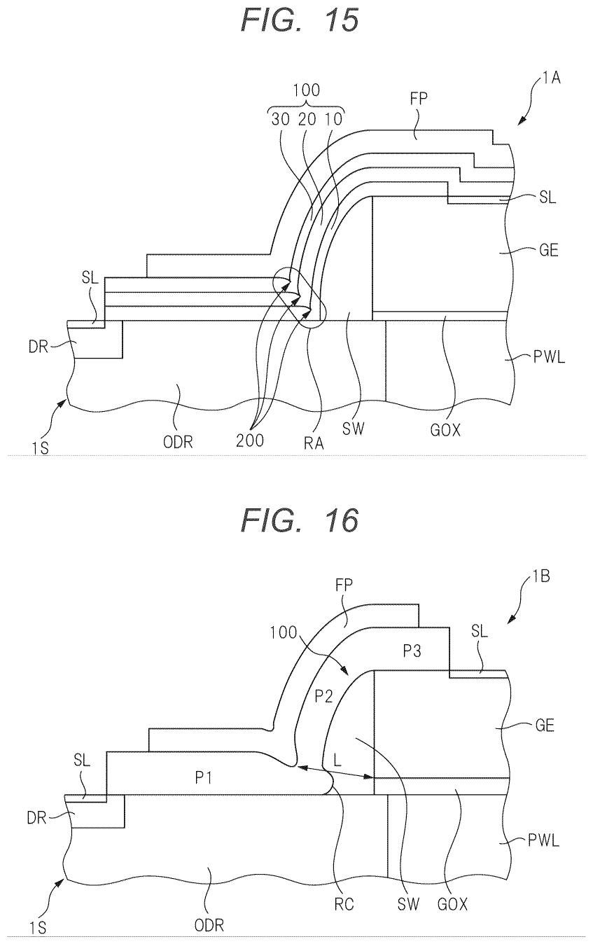

Next, FIG. 15 is an enlarged view showing a part of FIG. 14.

In a region RA shown in FIG. 15, the recess 200 is formed in the dielectric film 100. In detail, the recess 200 is formed in each of the dielectric films 10, 20, and 30 configuring the dielectric film 100. In this way, the LDMOSFET 1A included in the semiconductor device in the first modified example is configured.

### Features in First Modified Example

The feature in the first modified example is, for example, as shown in FIG. 15, that the recess 200 is formed in the region RA of the dielectric film 100 located under the field plate electrode FP. In detail, in the region RA, the recess 200 is formed in each of the dielectric film 10, the dielectric film 20, and the dielectric film 30. As a result, a part of the field plate electrode FP is buried in the recess 200 formed in the dielectric film 30, so the distance between the field plate electrode FP and the lower end of the gate electrode GE can decrease than the configuration without the recess 200.

As a result, the feature in the first modified example can suppress the decrease in breakdown voltage caused by the electric field concentration at the lower end of the gate electrode GE while reducing the on-resistance. Therefore, the first modified example can improve the performance of the semiconductor device including the LDMOSFET 1A.

Hereinafter, the advantages of the first modified example will be described.

In the first modified example, for example, as shown in FIGS. 13 and 14, the dielectric film 100 is formed of the dielectric film 10, the dielectric film 20, and the dielectric film 30, and each of the dielectric film 20 and the dielectric film 30 is formed to cover the gate electrode GE.

As a result, the first modified example can suppress short-circuit failures between the field plate electrode FP disposed on the dielectric film 30 and the gate electrode GE. In particular, according to the first modified example, even if a “patterning shift” occurs in the patterning when forming the field plate electrode FP, since the gate electrode GE is covered with the dielectric film 20 and the dielectric film 30, short-circuit failures between the field plate electrode FP and the gate electrode GE can be suppressed. Therefore, the first modified example can improve the reliability of the semiconductor device including the LDMOSFET 1A.

Furthermore, in the first modified example, the gate electrode GE is covered with the dielectric film 20 and the dielectric film 30. Therefore, according to the first modified example, a part of the field plate electrode FP can be disposed over the gate electrode GE without concern for short-circuit failures. From this, the first modified example can improve the layout freedom of the field plate electrode FP.

For example, as shown in FIG. 14, the field plate electrode FP can be disposed to cover the gate electrode GE. In this case, the same potential “0 V” as the source region SR is applied to the field plate electrode FP. Therefore, the field plate electrode FP covering the gate electrode GE functions as a shield between the gate electrode GE and the drain region DR. From this, according to the first modified example, as a result of the field plate electrode FP functioning as a shield, the “gate-drain capacitance” in LDMOSFET 1A can be reduced. That is, the first modified example can reduce the parasitic capacitance existing in the LDMOSFET 1A, and can improve the performance of the semiconductor device including the LDMOSFET 1A.

Furthermore, in the first modified example, a configuration that is less likely to affect the characteristics of the CMOSFET mixed with the LDMOSFET 1A will be described.

For example, as shown in FIG. 15, the dielectric film 100 is formed of the dielectric film 10, the dielectric film 20, and the dielectric film 30. Here, in the first modified example, as shown in FIG. 15, the recess 200 is formed in the dielectric film 100 in the region RA. In this case, from the viewpoint of forming the recess 200, each of the dielectric film 10, the dielectric film 20, and the dielectric film 30 can be formed using a film formation method that easily forms the recess 200 in the region RA. For example, the dielectric film 10, the dielectric film 20, and the dielectric film 30 are considered to be formed with low thickness uniformity, using a normal pressure CVD method or a plasma CVD method, rather than a low-pressure CVD method.

For example, the dielectric film 20 is formed from a silicon nitride film. The dielectric film 20 functions as a stressor in the so-called “strained silicon technique” that improves the mobility of carriers in the channel by applying stress (strain) to the LDMOSFET 1A. And, it is desirable that the stressor can apply stress uniformly, so it is desirable to be a film with high thickness uniformity. In this regard, a film with lower thickness uniformity than a film formed by a low-pressure CVD method is formed by a normal pressure CVD method or a plasma CVD method.

Therefore, it is desirable to form the dielectric film 20, which functions as a stressor, using a low-pressure CVD method rather than a normal pressure CVD method or a plasma CVD method. That is, in the first modified example, from the viewpoint of forming the recess 200 while securing the function as a stressor, it is desirable to form the dielectric film 10 and the dielectric film 30 using a normal pressure CVD method or a plasma CVD method, while the dielectric film 20 is formed using a low-pressure CVD method.

In this regard, the above-mentioned technique has little effect on the characteristics of the CMOSFET mixed with the LDMOSFET 1A. That is, the dielectric film 20 is formed to function as a stressor in the “strained silicon technique” not only in the LDMOSFET 1A but also in the CMOSFET. If the thickness uniformity of the dielectric film 20 is low, there is a risk that the dielectric film 20 will not function sufficiently as a good stressor even in the CMOSFET. From this, if the low thickness uniformity dielectric film 20 is formed using a normal pressure CVD method or a plasma CVD method to form the recess 200, there is a risk of adversely affecting the characteristics of the CMOSFET such as the mobility of carriers in the channel. In contrast, according to the above-mentioned technique, the dielectric film 20 is formed using a low-pressure CVD method. From this, the first modified example can improve the thickness uniformity of the dielectric film 20. This allows the formation of the recess 200 in the dielectric film 100 of the LDMOSFET 1A without significantly affecting the characteristics of the CMOSFET mixed with the LDMOSFET 1A. Therefore, the first modified example can improve the performance of the LDMOSFET 1A without adversely affecting the characteristics of the CMOSFET mixed with the LDMOSFET 1A.

### Second Modified Example

Next, an LDMOSFET 1B in the second modified example will be described.

FIG. 16 is an enlarged view showing the configuration between the field plate electrode FP and the lower end of the gate electrode GE in the LDMOSFET 1B. In FIG. 16, the feature of the second modified example is that a recess part RC is formed under the sidewall spacer SW.

As a result, the second modified example can reduce the “distance L” shown in FIG. 16. That is, according to the second modified example, forming the recess part RC under the sidewall spacer SW can decrease the distance between the field plate electrode FP and the lower end of the gate electrode GE than the configuration without the recess part RC.

As a result, according to the second modified example, even if the impurity concentration of the substrate 1S increases, equipotential lines are less likely to enter between the field plate electrode FP and the lower end of the gate electrode GE. Therefore, according to the second modified example, the LDMOSFET 1B can reduce the on-resistance while suppressing the reduction in breakdown voltage caused by electric field concentration at the lower end of the gate electrode GE. Therefore, the second modified example can improve the performance of the semiconductor device including the LDMOSFET 1B.

For example, the recess part RC can be formed by applying isotropic etching to the sidewall spacer SW in addition to the anisotropic etching for forming the sidewall spacer SW.

In the second modified example, the recess part RC is formed in the sidewall spacer SW. This allows for the formation of the conformal dielectric film 100 with high thickness uniformity, and the presence of the recess part RC can reduce the “distance L” between the field plate electrode FP and the lower end of the gate electrode GE. In other words, in the second modified example, a low-pressure CVD method capable of forming a film with high thickness uniformity can be used as a method of forming the dielectric film 100.

However, not only can the recess part RC be formed in the sidewall spacer SW, but a recess may also be formed in the dielectric film 100. In this case, the “distance L” can be further reduced by the recess part RC and the recess. That is, even in the second modified example, a recess may be formed in the dielectric film 100 by using a method of forming the dielectric film 100, such as a normal pressure CVD method or a plasma CVD method, instead of a low-pressure CVD method.

### Third Modified Example

Next, an LDMOSFET 1C in the third modified example will be described.

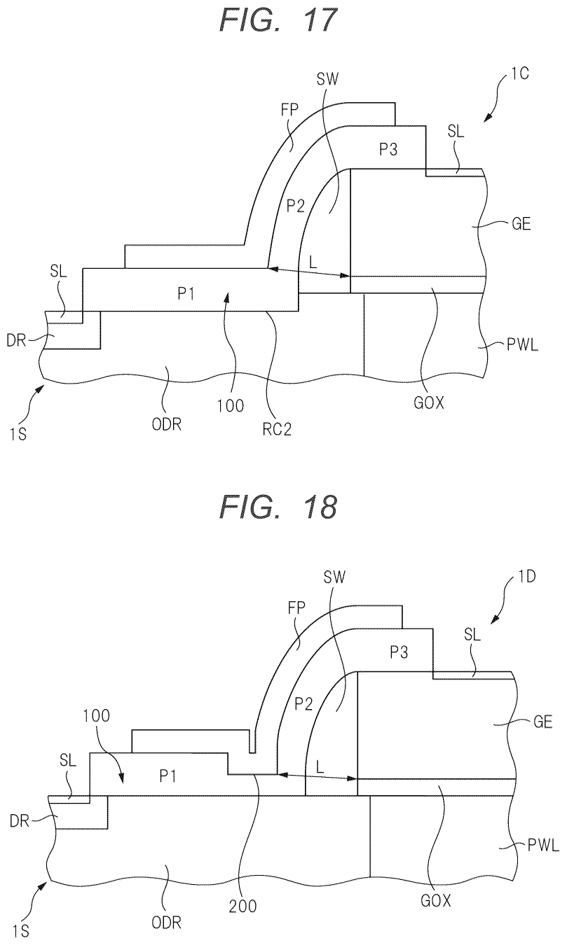

FIG. 17 is an enlarged view showing the configuration between the field plate electrode FP and the lower end of the gate electrode GE in the LDMOSFET 1C. In FIG. 17, the feature of the third modified example is that a recess part RC2 is formed at the upper surface of the substrate 1S.

As a result, the upper surface of the substrate 1S contacting the dielectric film 100 becomes lower than the upper surface of the substrate 1S contacting the sidewall spacer SW. As a result, the third modified example can reduce the “distance L” shown in FIG. 17. That is, the third modified example can decrease the “distance L” than a configuration without the recess part RC2 by forming the recess part RC2 at the upper surface of the substrate 1S.

As a result, according to the third modified example, even if the impurity concentration of the substrate 1S increases, equipotential lines are less likely to enter between the field plate electrode FP and the lower end of the gate electrode GE. Therefore, the LDMOSFET 1C in the third modified example can suppress a decrease in breakdown voltage caused by electric field concentration at the lower end of the gate electrode GE while reducing on-resistance. Therefore, the third modified example can improve the performance of the semiconductor device including the LDMOSFET 1C.

For example, the recess part RC2 can be formed by etching the substrate 1S using the sidewall spacer SW as a mask.

In the third modified example, the recess part RC2 is formed in the substrate 1S. This allows for the formation of the conformal dielectric film 100 with high thickness uniformity, and the presence of the recess part RC2 can reduce the “distance L” between the field plate electrode FP and the lower end of the gate electrode GE. In other words, in the third modified example, a low-pressure CVD method capable of forming a film with high thickness uniformity can be used as a method of forming the dielectric film 100.

Not only can the recess part RC2 be formed in the substrate 1S, but a recess may also be formed in the dielectric film 100. In this case, the “distance L” can be further reduced by the recess part RC2 and the recess. That is, even in the third modified example, the recess may be formed in the dielectric film 100 by using a method of forming the dielectric film 100, such as a normal pressure CVD method or a plasma CVD method, instead of a low-pressure CVD method.

### Fourth Modified Example

Next, an LDMOSFET 1D in the fourth modified example will be described.

FIG. 18 is an enlarged view showing the configuration between the field plate electrode FP and the lower end of the gate electrode GE in the LDMOSFET 1D. In the fourth modified example, as shown in FIG. 18, the recess 200 is formed in the dielectric film 100 by patterning using a photolithography technique and an etching technique. Thus, the recess 200 may be formed by patterning. In this case as well, forming the recess 200 in the dielectric film 100 can reduce the “distance L” between the field plate electrode FP and the lower end of the gate electrode GE.

### Fifth Modified Example

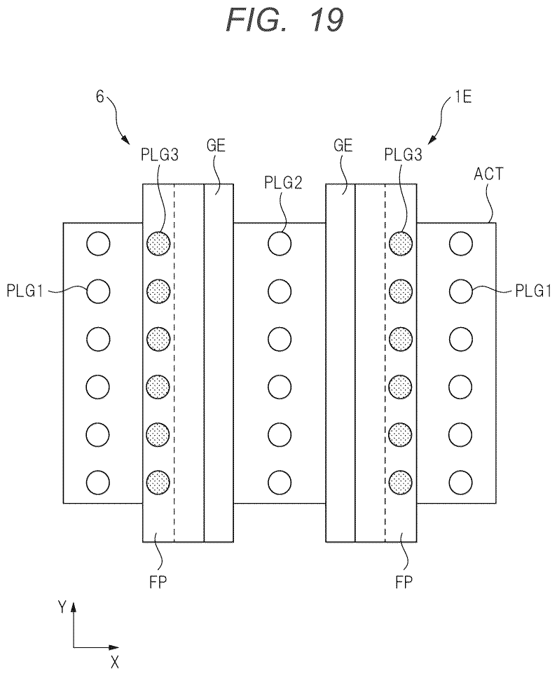

FIG. 19 is a plan view showing a schematic configuration of a semiconductor device including an LDMOSFET 1E in the fifth modified example. As shown in FIG. 19, the gate electrode GE of the LDMOSFET 1E extends in the Y direction on an active region ACT in plan view.

And, in plan view, the field plate electrode FP extends in the Y direction while partially overlapping the gate electrode GE. That is, although not shown in FIG. 19, a part of the field plate electrode FP extends in the Y direction in plan view so as to overlap the active region ACT between the drain region DR and the sidewall spacer SW.

Here, the feature of the fifth modified example is that, for example, as shown in FIG. 19, a part of the field plate electrode FP is electrically connected to a plurality of plugs PLG3. That is, wiring (not shown) is formed to overlap the field plate electrode FP in plan view, and the field plate electrode FP and the above-mentioned wiring are connected via the plurality of plugs PLG3 shown in FIG. 19.

As a result, the fifth modified example can strengthen the electrical connection between the field plate electrode FP and the plug PLG3. In particular, when a recess is formed in the dielectric film located under the field plate electrode FP, the thickness uniformity of the field plate electrode FP is considered to decrease. In this case, a part having a small thickness is formed in the field plate electrode FP, and as a result, the resistance value of the field plate electrode FP may increase due to this part having a small thickness. Therefore, in the fifth modified example, the plurality of plugs PLG3 are connected to the field plate electrode FP. This can reduce the resistance value of the field plate electrode FP. That is, according to the fifth modified example, the increase in the resistance component due to the decrease in the thickness uniformity of the field plate electrode FP is reduced by connecting the field plate electrode FP and the plurality of plugs PLG3. As a result, the fifth modified example can improve the performance of the semiconductor device including the LDMOSFET 1E.

### Sixth Modified Example

Next, an LDMOSFET 1F in the sixth modified example will be described.

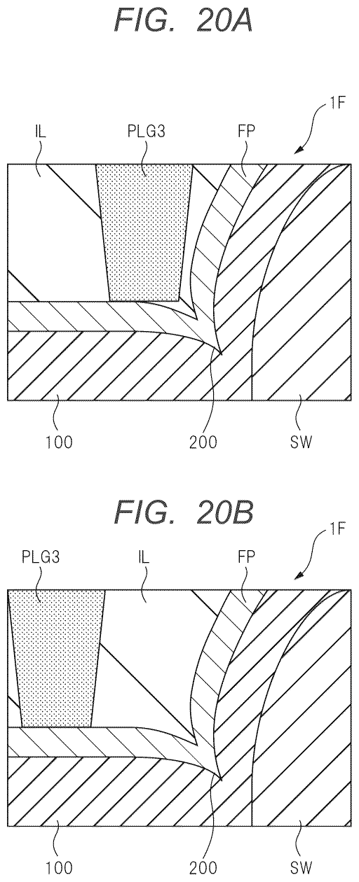

FIGS. 20A and 20B are enlarged views showing the configuration between the field plate electrode FP and the sidewall spacer SW. In FIG. 20A, an example is shown in which the plug PLG3 connected to the field plate electrode FP is disposed near the recess 200. That is, the plug PLG3 is disposed to overlap the recess 200.

As shown in FIG. 20A, if the plug PLG3 is disposed near the recess 200, a connection failure between the field plate electrode FP and the plug PLG3 may occur due to the shape of the recess 200.

On the other hand, FIG. 20B shows the LDMOSFET 1F in the sixth modified example. Specifically, in FIG. 20B, the plug PLG3 connected to the field plate electrode FP is disposed away from the recess 200. That is, the plug PLG3 is disposed so as not to overlap the recess 200.

As shown in FIG. 20B, by disposing the plug PLG3 away from the recess 200, the field plate electrode FP and the plug PLG3 can be connected without being affected by the shape of the recess 200. As a result, the sixth modified example can improve the reliability of the semiconductor device including the LDMOSFET 1F.

The invention made by the present inventor has been described above in detail based on the embodiment, but the present invention is not limited to the embodiment described above, and it is needless to say that various modifications can be made without departing from the gist thereof.

In this specification, the epitaxial layer EPI into which n-type impurities are introduced is described, but the epitaxial layer EPI into which p-type impurities are introduced may be applied. When applying the epitaxial layer EPI into which p-type impurities are introduced, the epitaxial layer EPI may have, for example, a buried semiconductor layer and a drift layer. The buried semiconductor layer is formed to electrically isolate the LDMOSFET from the semiconductor substrate. The drift layer has a lower impurity concentration than the drain region DR, and is formed towards the gate electrode GE from the drain region DR, similar to the offset drain region ODR.

What is claimed is:

1. A semiconductor device comprising:
a semiconductor substrate;
a source region formed in the semiconductor substrate;
a drain region formed in the semiconductor substrate and separated from the source region;
a gate dielectric film formed on the semiconductor substrate;
a gate electrode formed on the semiconductor substrate;
a sidewall spacer formed on a side surface of the gate electrode;
a dielectric film formed so as to contact a part of an upper surface of the gate electrode, the sidewall spacer and the semiconductor substrate; and
a field plate electrode formed on the dielectric film,
wherein a recess is formed at an upper surface of the dielectric film and between the drain region and the gate electrode, and
wherein a part of the field plate electrode is buried in the recess.

2. The semiconductor device according to claim 1,
wherein the dielectric film comprises:
a first part contacting the semiconductor substrate;
a second part contacting the sidewall spacer; and
a third part contacting the part of the upper surface of the gate electrode,
wherein the recess is formed at a connection point between an upper surface of the first part and an upper surface of the second part.

3. The semiconductor device according to claim 1,
wherein a first distance between an upper surface of the semiconductor substrate and the recess is greater than a thickness of the gate dielectric film.

4. The semiconductor device according to claim 2,
wherein an unevenness corresponding to a surface roughness is formed at the upper surface of the first part, and
wherein a first difference between the highest position of the unevenness and a lower end of the recess is greater than a second difference between the highest position of the unevenness and the lowest position of the unevenness.

5. The semiconductor device according to claim 4,
wherein the first difference is greater than 2 nm.

6. The semiconductor device according to claim 1,
wherein a distance between the gate electrode and the drain region is greater than a distance between the gate electrode and the source region.

7. The semiconductor device according to claim 1,
wherein the field plate electrode is formed of a metal silicide film.

8. The semiconductor device according to claim 1,
wherein the dielectric film comprises:
a first dielectric film formed so as to contact the part of the upper surface of the gate electrode, the sidewall spacer and the semiconductor substrate;
a second dielectric film formed so as to contact the other part of the upper surface of the gate electrode and the first dielectric film and to cover the gate electrode; and
a third dielectric film formed so as to contact the second dielectric film.

9. The semiconductor device according to claim 8,
wherein a thickness uniformity of the second dielectric film is higher than a thickness uniformity of each of the first dielectric film and the third dielectric film.

10. The semiconductor device according to claim 8,
wherein the field plate electrode extends so as to cover the gate electrode and to be electrically connected to the source region.

11. The semiconductor device according to claim 1,
wherein a recess part is formed at a lower part of the sidewall spacer.

12. The semiconductor device according to claim 1,
wherein an upper surface of the semiconductor substrate contacting the dielectric film is lower than the upper surface of the semiconductor substrate contacting the sidewall spacer.

13. The semiconductor device according to claim 1,
wherein a part of the field plate electrode extends in a gate width direction of the gate electrode in plan view so as to overlap an active region between the drain region and the sidewall spacer, and
wherein the part of the field plate electrode is electrically connected to a plurality of plugs.

14. The semiconductor device according to claim 1, comprising:
a plug connected to the field plate electrode,
wherein the plug is disposed to be separated from the recess.

15. A method of manufacturing a semiconductor device, the method comprising:
(a) forming a gate electrode on a semiconductor substrate via a gate dielectric film;
(b) forming a sidewall spacer on a side surface of the gate electrode;
(c) forming a dielectric film so as to contact a part of an upper surface of the gate electrode, the sidewall spacer and the semiconductor substrate; and
(d) forming a field plate electrode on the dielectric film,
wherein in the (c), the dielectric film is formed by using an normal pressure CVD method or a plasma CVD method.

16. The method according to claim 15,
wherein the dielectric film comprises:
a first part contacting the semiconductor substrate;
a second part contacting the sidewall spacer; and
a third part contacting the part of the upper surface of the gate electrode,
wherein a recess is formed at a connection point between an upper surface of the first part and an upper surface of the second part, and
wherein a part of the field plate electrode is buried in the recess.
